(19) United States
(12) Patent Application Publication
(10) Pub. No.: US 2017/0126116 A1
(43) Pub. Date: May 4, 2017

(54) APPARATUS FOR CONTROLLING A SEMICONDUCTOR SWITCH

(71) Applicant: Cooper Technologies Company, Houston, TX (US)

(72) Inventor: Mark Steven George, Wilsonville, OR (US)

(21) Appl. No.: 14/925,568

(22) Filed: Oct. 28, 2015

(51) Int. Cl. H02M 3/07; H03K 17/56

(52) U.S. Cl. CPC H02M 3/07; H03K 17/56

(57) ABSTRACT

An apparatus includes an electrical network configured for connection to a first terminal of a semiconductor switch; a first voltage source connected to the electrical network; a second voltage source configured for connection to a second terminal of the semiconductor switch and to the first voltage source, the second voltage source includes a capacitive element configured to store electrical charge, the capacitive element receiving and storing electrical charge when the electrical network and the semiconductor switch conduct current, and the second voltage source providing a voltage based on the capacitive element, the voltage provided by the second voltage source bringing the second terminal of the semiconductor switch to a voltage that is greater than the lowest voltage that a third terminal of the semiconductor switch receives.

### TECHNICAL FIELD

This disclosure relates to an apparatus for controlling a semiconductor switch.

### BACKGROUND

A semiconductor switch has three terminals. In an ON state, current flows from a first terminal to a second terminal, and in an OFF state, current does not flow between the first and second terminals. The state of the semiconductor switch can be controlled by applying a voltage between a third terminal and the second terminal of the semiconductor switch. To transition to the OFF state, or to transition to the OFF state quickly, some semiconductor switches require a negative voltage between the third terminal and the second terminal.

### SUMMARY

In one general aspect, an apparatus includes: an electrical network configured for connection to a first terminal of a semiconductor switch; a first voltage source connected to the electrical network; a second voltage source configured for connection to a second terminal of the semiconductor switch and to the first voltage source, the second voltage source includes a capacitive element configured to store electrical charge, the capacitive element receiving and storing electrical charge when the electrical network and the semiconductor switch conduct current, and the second voltage source providing a voltage based on the capacitive element, the voltage provided by the second voltage source bringing the second terminal of the semiconductor switch to a voltage that is greater than the lowest voltage that a third terminal of the semiconductor switch receives.

Implementations may include one or more of the following features. In some implementations, the semiconductor switch does not conduct current when the voltage of the third terminal of the semiconductor switch relative to the second terminal of the semiconductor switch is less than an OFF voltage, and the voltage provided by the second voltage source brings the second terminal of the semiconductor switch to a voltage that is greater than the lowest voltage that the third terminal of the semiconductor switch receives by an amount that is at least equal to the OFF voltage. The OFF voltage of the semiconductor switch may be less than zero.

A voltage regulator may be connected to the second voltage source. The voltage regulator may include a Zener diode, and the Zener diode may be connected in parallel with the capacitive element of the second voltage source. The capacitive element of the second voltage source may include a single capacitor. The capacitive element of the second voltage source may receive electrical charge from the first voltage source when the electrical network and the semiconductor switch conduct current.

The electrical network may include a diode. The electrical network may be configured to conduct current when the semiconductor switch conducts current from the first terminal of the semiconductor switch to the second terminal of the semiconductor switch.

The apparatus also may include amplifier, and the amplifier may include an input terminal, an output terminal, a high power supply terminal, and a low power supply terminal. The output terminal of the amplifier may be connected to the third terminal of the semiconductor switch, the high power supply terminal of the amplifier is connected to the first voltage source, and the low power supply terminal of the amplifier is connected to the second voltage source. The lowest voltage that the third terminal of the semiconductor switch receives may be the voltage of the low power supply terminal of the amplifier. The apparatus also may include the semiconductor switch. The semiconductor switch may be one of a silicon carbide (SiC) metal-oxide semiconductor field-effect (MOSFET) transistor and an insulated-gate bipolar transistor (IGBT).

In another general aspect, a method of controlling a semiconductor switch includes connecting an electrical network to a first terminal of the semiconductor switch, the semiconductor switch including the first terminal, a second terminal, and a third terminal, the semiconductor switch conducting current from the first terminal to the second terminal in an ON state and not conducting current from the first terminal to the second terminal in an OFF state, conducting current through the electrical network when current flows from the first terminal of the semiconductor switch to the second terminal of the semiconductor switch to charge a capacitive element, the capacitive element being connected to the second terminal of the semiconductor switch; providing a voltage at the second terminal based on the charge in the capacitive element, the provided voltage bringing the second terminal of the semiconductor switch to a voltage that is greater than the lowest voltage that the third terminal of the semiconductor switch receives; and applying an input voltage to the third terminal of the semiconductor switch, the input voltage bringing the voltage of the third terminal to a voltage that is less than the voltage at the second terminal of the semiconductor switch to transition the semiconductor switch to the OFF state.

Implementations may include one or more of the following features. Conducting current through the electrical network may include conducting current through a forward biased diode and a resistive element, the resistive element limiting the amount of charge that flows to the capacitive element. Conducting current through the electrical network when current flows from the first terminal of the semiconductor switch to the second terminal of the semiconductor switch to charge the capacitive element may include charging the capacitive element to a voltage that is no greater than a reverse voltage of a Zener diode in parallel with the capacitive element, and also may include providing a voltage at the second terminal based on the charge in the capacitive element. The provided voltage may bring the second terminal of the semiconductor switch to a voltage that is greater than the lowest voltage that the third terminal of the semiconductor switch receives. The voltage provided to the second terminal may be a regulated voltage.

In another general aspect, a negative charge pump apparatus for connection to a semiconductor switch includes an electrical network. The electrical network includes a diode, and a resistive element in series with the diode; and a voltage source configured for connection to the resistive element of the electrical network through the semiconductor switch. The voltage source includes a capacitive element, and a Zener diode in parallel with the capacitive element.

Implementations may include one or more of the following features. The capacitive element of the floating voltage source may be a single capacitor. The voltage source also may include a second resistive element connected in parallel with the Zener diode and the capacitor. The negative charge pump apparatus also may another voltage source, and the other voltage source may be connected between the electrical network and the voltage source.

### DRAWING DESCRIPTION

FIGS. 1-3 are block diagrams of example systems that include a driving apparatus for a semiconductor switch.

FIG. 4 is a flow chart of an example process for controlling a semiconductor switch.

### DETAILED DESCRIPTION

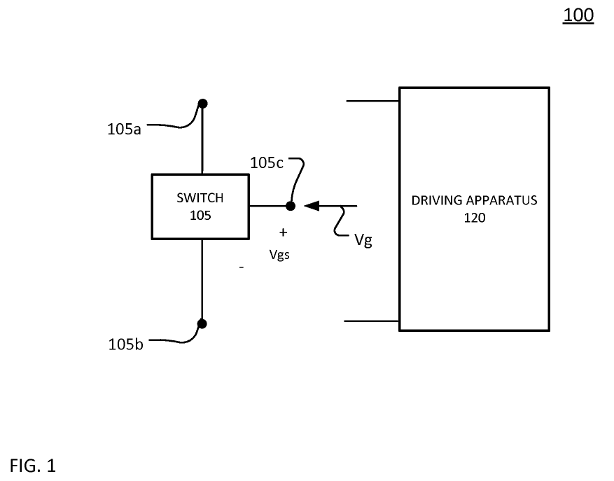

Referring to FIG. 1, a block diagram of a system 100 is shown. The system 100 includes a semiconductor switch 105 and a driving apparatus 120, which is connectable to the semiconductor switch 105. The driving apparatus 120 drives the semiconductor switch 105 to transition from an ON state to an OFF state and vice versa. The semiconductor switch 105 may be a voltage-controlled power semiconductor switch, such as, for example, a silicon carbide (SiC) metal-oxide semiconductor field effect transistor (MOSFET), an insulated-gate bipolar transistor (IGBT), a gallium arsenide (GaS) MOSFET, any other type of MOSFET, or any type of three-terminal, voltage-controlled power semiconductor switching device. The semiconductor switch 105 applies power to a load (not shown). The amount of power applied to the load is controlled by the switching duty ratio (d), which is the portion of time during a switching cycle that the semiconductor switch 105 is in the ON state.

In use, the driving apparatus 120 is connected to first and second terminals 105a, 105b of the semiconductor switch 105. The driving apparatus 120 ensures that a voltage signal (Vg) provided to a third terminal 105c of the semiconductor switch 105 can transition the semiconductor switch 105 to the OFF state. As discussed in greater detail below, the driving apparatus 120 provides a simple circuit that uses one external voltage source and a negative charge pump. The negative charge pump is used instead of a second external voltage source.

A charge pump is a direct current (DC) to DC converter that uses a capacitive element to create a voltage source. The charge pump formed in the driving apparatus 120 generates a regulated negative voltage (a voltage that is less than zero) from electrical charge that flows from the external voltage source. The charge pump of the driving apparatus 120 is charged while the semiconductor switch 105 is in the ON state. Thus, in addition to applying power to a load according to the switching duty ratio (d), the current that flows through the semiconductor switch 105 has a secondary function of providing electrical charge to the charge pump.

The switch 105 has three terminals: a first terminal 105a, a second terminal 105b, and third terminal 105c. The semiconductor switch 105 can be any type of semiconductor switch that transitions between an ON state in which current is conducted between the first terminal 105a and the second terminal 105b and an OFF state in which current does not flow. For example, in implementations in which the semiconductor switch 105 is a SiC MOSFET, the first terminal 105a is the drain, the second terminal 105b is the source, and the third terminal 105c is the gate. In implementations in which the semiconductor switch 105 is an IGBT, the first terminal 105a is the collector, the second terminal 105b is the emitter, and the third terminal 105c is the base.

The voltage difference (V_{gs}) between the third terminal 105c and the second terminal 105b determines the state of the semiconductor switch 105. When V_{gs} is greater than a nominal threshold voltage (Vₜₕ), current begins to flow from the first terminal 105a to the second terminal 105b, and the semiconductor switch 105 is in the ON state. When V_{gs} is less than Vₜₕ, the semiconductor switch 105 is in the OFF state, and current does not flow from the first terminal 105a to the second terminal 105b.

In the ON state, the resistance between the first terminal 105a and the second terminal 105b is referred to as the “on-resistance” (R_{ds ON}). The on-resistance decreases as V_{gs} increases. Because current flows from the first terminal 105a to the second terminal 105b in the ON state, a lower on-resistance may result in a lower amount of heat produced by the semiconductor switch 105. Thus, to ensure efficient operation, it is generally desirable to conduct current from the first terminal 105a to the second terminal 105 at a V_{gs} that is associated with a relatively low on-resistance value. As such, although the semiconductor switch 105 is in the ON state when V_{gs} is greater than the threshold voltage Vₜₕ, the semiconductor switch 105 may be considered to be “fully on” and in a saturation region when V_{gs} is well above the nominal threshold Vₜₕ, at a voltage at which the on-resistance is relatively low. The semiconductor switch 105 is operated at a V_{gs} at which the switch 105 is fully on to deliver current to the load.

When V_{gs} is greater than the nominal threshold voltage Vₜₕ but less than a voltage at which the semiconductor switch is considered fully on, the semiconductor switch 105 is in the ON state but in the linear (or ohmic) region. In the linear region, the on-resistance is relatively high. Thus, although the semiconductor switch 105 is in the ON state when operating in the linear region, it is desirable to transition the semiconductor switch 105 from being fully on to the OFF state quickly because the on-resistance is greater in the linear region than when the semiconductor switch 105 is fully on (in the saturation region).

Thus, when in the ON state, the semiconductor switch 105 is operated at a V_{gs} that is is well above the nominal threshold voltage (Vₜₕ) associated with the switch. For example, a SiC MOSFET may have a nominal threshold voltage of 2.5V but not be fully on until V_{gs} is 12-20V. The on-resistance (R_{ds ON}) may be, for example, 80-150 milliohms (mΩ) when V_{gs} is 20V, greater than 200 mΩ when V_{gs} is 10V, and even greater at the nominal threshold voltage of 2.5V.

Furthermore, in some implementations, a negative V_{gs} (a V_{gs} less than 0V, with the voltage of the second terminal 105b being greater than the voltage of the third terminal 105c) is needed to transition the semiconductor switch 105 to the OFF state. Even in configurations of the semiconductor switch 105 that can be transitioned to the OFF state with a V_{gs} that is 0V, using a negative V_{gs} may transition the semiconductor switch 105 to the OFF state more quickly. As discussed above, the on-resistance is relatively high in the linear region. Thus, because the semiconductor switch 105 may consume more power in the linear region than when fully on (or in the saturation region), it is desirable to transition the semiconductor switch 105 from being fully on to the OFF state as quickly as possible.

As discussed below, the driving apparatus 120 controls the semiconductor switch 105 such that the switch 105 can transition from being in the ON state (in particular, from being fully on or in the saturation region) to the OFF state quickly and completely. This allows the semiconductor switch 105 to be in the linear region for only a small amount of time, thereby reducing heat loss. Additionally, the driving apparatus 120 uses a negative charge pump to drive the third terminal 105b to a voltage that is lower than the second terminal 105c. In this way, the driving apparatus 120 also makes V_{gs} 0V or less, ensuring that the semiconductor switch 105 is transitioned to the OFF state.

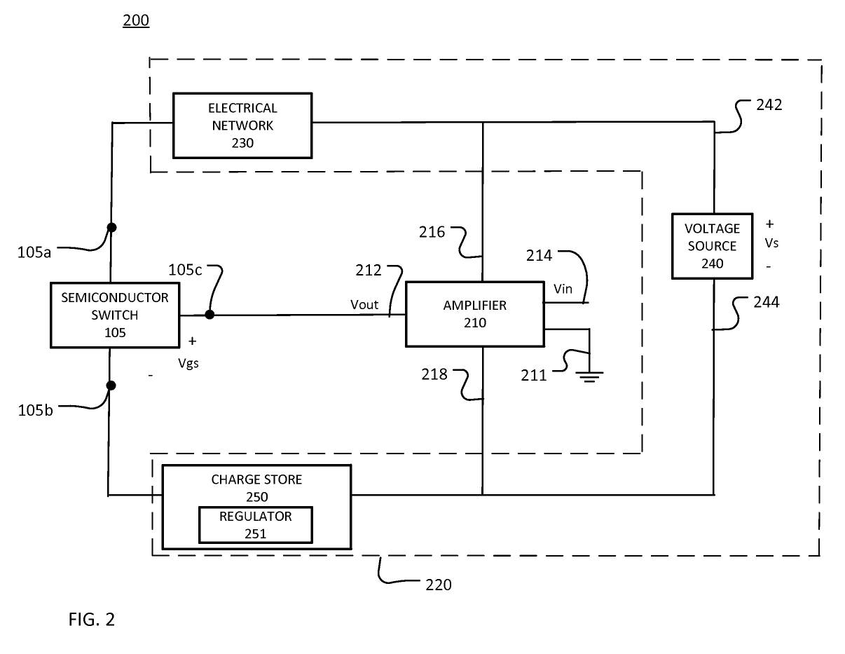

Referring to FIG. 2, a block diagram of another example system 200 that includes the semiconductor switch 105 and a driving apparatus 220 is shown.

The driving apparatus 220 includes an electrical network 230, a voltage source 240, and a charge store 250. The driving apparatus 220 is connected to the first terminal 105a of the semiconductor switch 105, and the charge store 250 is connected to the second terminal 105b of the semiconductor switch 105. The voltage source 240 is connected between the electrical network 230 and the charge store 250.

Together, the semiconductor switch 105, the electrical network 230, and the charge store 250 form a negative charge pump that provides a voltage to the second terminal 105b of the semiconductor switch 105. The electrical network 230 is an electronic component, or a collection of electronic components, that controls current flow from the voltage source 240 to the charge store 250. The electrical network 230 allows current to flow in one direction, and the electrical network 230 also can limit the amount of current that flows to the charge store 250.

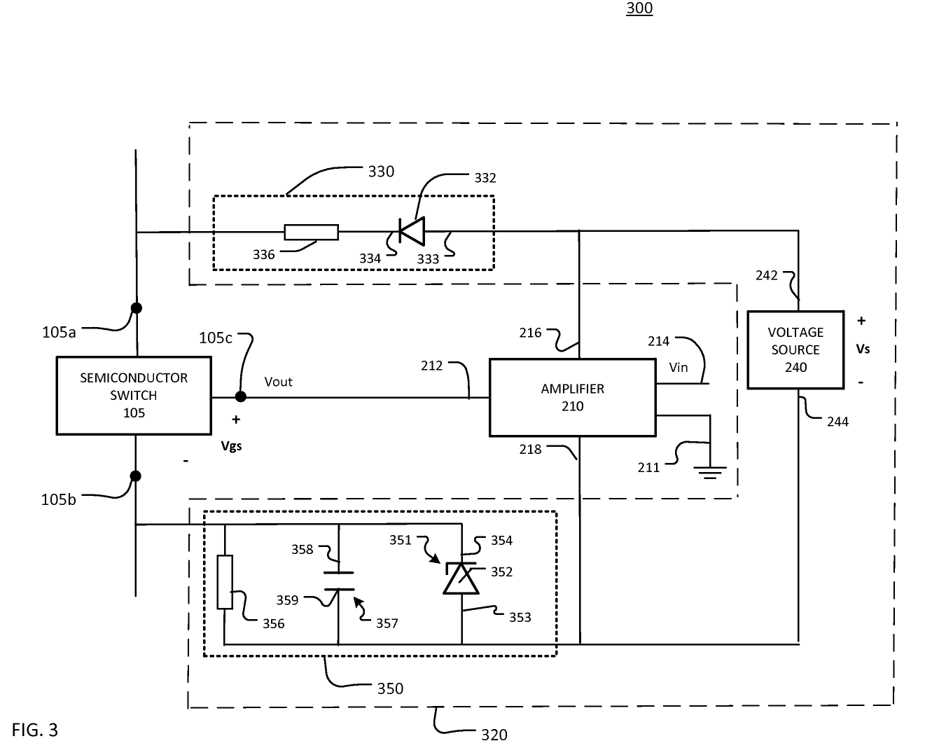

The driving apparatus 220 also can include a voltage regulator 251. When in operation, the voltage regulator 251 has a constant DC voltage, or a voltage remains within a range of voltages, between its terminals. The voltage regulator 251 also provides an upper limit on the amount of voltage that is applied to the charge store 250. The voltage regulator 251 can be a shunt regulator that is connected in parallel with an element or elements in the charge store 250 that store electrical charge, or the voltage regulator 250 can be a series pass voltage regulator that is connected in series with the element or elements that store electrical charge. An example of the voltage regulator 251 in a shunt regulator configuration is shown in FIG. 3.

The system 200 also includes an amplifier 210, which provides a voltage signal (Vₒᵤₜ) to the third terminal 105c of the semiconductor switch 105 through an output terminal 212. The amplifier 210 also includes an input terminal 214, a high power supply terminal 216, and a low power supply terminal 218. The amplifier 210 has a low output impedance (for example, 5 ohms or less). The input terminal 214 receives a voltage signal (Vᵢₙ) that is referenced to a system ground 211. The voltage signal (Vᵢₙ) is amplified by the amplifier 210 (the voltage signal (Vᵢₙ) is multiplied by a gain (G) associated with the amplifier 210) to produce the output signal (Vₒᵤₜ). The amplifier 210 receives power at the high power supply terminal 216 and the low power supply terminal 218. The voltage at the power supply terminals 216, 218 is V_{H} and V_{L}, respectively. The voltage of the output signal (Vₒᵤₜ) is limited by the voltage at the power supply terminals 216, 218 and falls between V_{H} and V_{L}.

The voltage source 240 includes a high terminal 242, which is connected to the high power supply terminal 216 and the electrical network 230, and a low terminal 244, which is connected to the charge store 250 and the low power supply terminal 218 of the amplifier 210. The high terminal 242 is at a higher voltage than the low terminal 244, and the voltage difference between the high terminal 242 and the low terminal 244 is the voltage provided by the voltage source 240 (Vs). The voltage source 240 is an external voltage source (such as a flyback converter). The voltage source 240 may be referenced to the system ground 211, or the voltage source 240 may be a floating voltage source (a voltage source that is not referenced to the system ground 211). The second terminal 105b of the semiconductor switch 105 floats with respect to the low terminal 244 of the voltage source 240, regardless of whether or not the voltage source 240 is a floating voltage source.

Referring to FIG. 3, a block diagram of a system 300 that includes an example of a driving apparatus 320 is shown. The driving apparatus 320 includes an electrical network 330, the voltage source 240, and a charge store 350. The driving apparatus 320 controls the state of the semiconductor switch 105, transitioning the semiconductor switch 105 from an ON state and an OFF state and vice versa. The driving apparatus 320 is connected to the first terminal 105a and the second terminal 105b of the semiconductor switch 105. The third terminal 105c of the semiconductor switch 105 receives the output voltage (Vₒᵤₜ) from the amplifier 210. Together, the semiconductor switch 105, the electrical network 330, and the charge store 350 form a negative charge pump.

In the example of FIG. 3, the electrical network 330 includes a diode 332 and a resistive element 336, and the electrical network 330 is connected between the first terminal 105a of the semiconductor switch 105 and the high terminal 242 of the voltage source 240. The diode 332 includes an anode 333 and a cathode 334, and the diode 332 and the resistive element 336 are in series. In the example of FIG. 3, the anode 333 is connected to the high terminal 242 of the voltage source 240, and the resistive element 336 is connected to the cathode 334. However, the diode 332 and the resistive element 336 can be connected in any series configuration. For example, the resistive element 336 can be connected to the high terminal 242 of the voltage source 240. Current flows through the diode 332 from the anode 333 to the cathode 334 when the voltage across the diode 332 is greater than the forward voltage associated with the diode 332. Otherwise, the diode 332 is reversed biased and does not conduct current.

The charge store 350 is connected between the second terminal 105b of the semiconductor switch 105 and the low power supply terminal 218 of the amplifier 210. The charge store 350 includes a regulator 351, a resistive element 356, and a capacitive element 357, which has first and second terminals 358, 359, respectively.

The regulator 351 places an upper bound or limit on the amount of voltage that is placed across the elements of the charge store 350, limiting the amount of charge that is stored in the charge store 350 and ensuring that the semiconductor switch 105 is not damaged. In the example of FIG. 3, the regulator 351 is a Zener diode 352, which has an anode 353 and a cathode 354. The Zener diode 352 is in parallel with the resistive element 356 and the capacitive element 357. In this configuration, the Zener diode 352 acts as a shunt regulator.

The regulator 351 can have other forms. The regulator 351 may be any electrical network or component that limits the voltage across the capacitive element 357 by providing a variable resistance current path. For example, the regulator 351 may be an integrated circuit or other electrical network that has an impedance that varies with voltage and is placed in parallel with the capacitive element 357. The regulator 351 may be a series pass regulator (or series pass element), which is connected in series with the capacitive element 357. The resistance of the series pass regulator changes such that the voltage drop across the series pass regulator also varies, resulting in a constant voltage across the series pass regulator, which in turn also results in the voltage across the capacitive element 357 remaining constant or within a limited range of voltages.

The capacitive element 357 may be any electrical network that is capable of storing electrical charge. For example, the capacitive element 357 may be a network of capacitors, each including two metal plates and a dielectric material between the two plates, arranged in series, parallel, or a combination of series and parallel capacitors. In some implementations, the capacitive element 357 is a single capacitor.

The Zener diode 352, the resistive element 356, and the capacitive element 357 are connected to each other in parallel. The anode 353 of the Zener diode is connected to the low power supply terminal 218 of the amplifier 210 and the low terminal 244 of the voltage source 240. The Zener diode 352 has a reverse breakdown voltage (V_{z}). When the voltage of the cathode 354 is (V_{z}) greater than the voltage of the anode 353, the Zener diode 352 operates in reverse breakdown mode, and current flows from the cathode 354 to the anode 353. When the Zener diode 352 is in the reverse breakdown mode, the voltage drop from the cathode 354 to the anode 353 remains approximately constant at (V_{z}). Thus, the voltage from the first terminal 358 to the second terminal 359 of the capacitive element 357, which is in parallel with the Zener diode 352, also remains approximately constant at (V_{z}).

When the semiconductor switch 105 conducts current from the first terminal 105a to the second terminal 105b, the diode 332 is forward biased and conducts current from the anode 333 to the cathode 334 and through the resistive element 336, which is in series with the diode 332. Current flows to the capacitive element 357, delivering electrical charge from the electrical network 330 and the voltage source 240 to the capacitive element 357. The resistive element 336 limits and determines the amount of current that reaches the capacitive element 357 and the Zener diode 352. In this way, the resistive element 336 protects the Zener diode 352 and the capacitive element 357. The resistive element 336 may be, for example, one or more resistors arranged in any configuration.

The capacitive element 357 stores the electrical charge, charging until the voltage difference between the first terminal 358 and the second terminal 359 (the voltage across the capacitive element 357) increases up to V_{z}. Thus, the charge store 350 stores (in the capacitive element 357) and controls (through the Zener diode 352) electrical charge. When the semiconductor switch 105 is in the OFF state, current does not flow from the first terminal 105a to the second terminal 105b of the semiconductor switch 105. The electrical charge that is stored in the capacitive element 357 is limited by the voltage (V_{z}) that is across the capacitive element 357, and the voltage across the capacitive element 357 is no more than V_{z}.

After the capacitive element 357 is charged, V_{gs} is equal to (V_{L}−V_{c}), where V_{L} is the voltage of the power supply terminal 218, and V_{c} is the voltage across the charge store 350. The third terminal 105c is thus driven to a voltage that is lower than the voltage of the second terminal 105b, resulting in V_{gs} being less than 0V and allowing the semiconductor switch 105 to be transitioned to the OFF state.

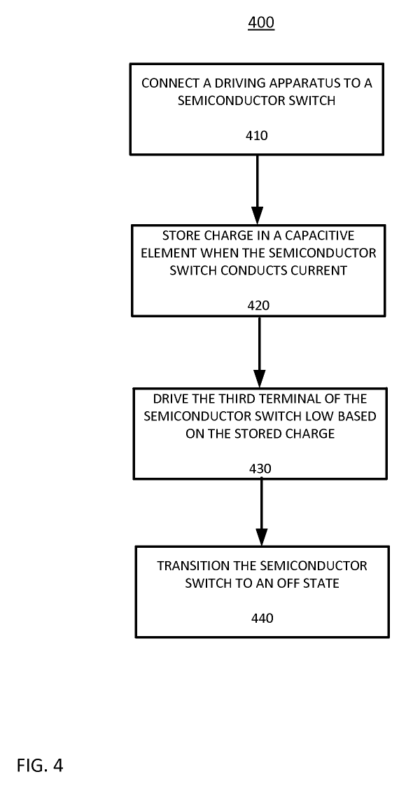

Referring also to FIG. 4, a flow chart of an example process 400 for controlling the semiconductor switch 105 is shown. FIG. 4 is discussed with respect to the system 300 and the driving apparatus 320 of FIG. 3.

The driving apparatus 320 is connected to the semiconductor switch 105 (410). The driving apparatus 320 may be connected to the semiconductor switch 105 by connecting the electrical network 330 to the first terminal 105a of the semiconductor switch 105, and the charge store 350 to the second terminal 105b of the semiconductor switch 105. The electrical network 330 is connected between the first terminal 105a and the high terminal 242 of the voltage source 240. The electrical network 330 conducts current from the anode 333 to the cathode 334 when the diode 332 is forward biased (when the voltage at the anode 333 is greater than the voltage at the cathode 334 by the forward voltage associated with the diode). The diode 332 can become forward biased when the semiconductor switch 105 conducts current from the first terminal 105a to the second terminal 105b. Additionally, the Zener diode 352 is reverse biased, causing the voltage across the capacitive element 357 to be V_{z}.

When the semiconductor switch conducts current from the first terminal 105a to the second terminal 105b, current flows through the electrical network 330, allowing electrical charge from the voltage source 240 to flow into the capacitive element 357 so that electrical charge is stored in the charge store 350 (420). The capacitive element 357 receives and stores the electrical charge, and the capacitive element 357 is charged to a voltage that is no greater than the reverse breakdown voltage (V_{z}) of the Zener diode 352. Because the charge store 350 is connected to the second terminal 105b of the semiconductor switch 105, the voltage of the second terminal 105b relative to the low terminal 218 is based on the amount of charge stored in the capacitive element 357. As a result, the voltage of the third terminal 105c can be driven to be below the voltage of the second terminal 105b, and V_{gs} can be less than 0V (430).

Additionally, the Zener diode 352 regulates the voltage that the charge store 350 provides by holding the voltage across the capacitive element 357 to V_{z}. In some implementations, the Zener diode 352 can limit the voltage provided by the charge store 350 to voltages that vary by 1% or less. Because the reverse bias mode of the Zener diode 352 is used to limit the voltage of the charge store 350, the voltage that is provided by the charge store 350 may be determined through selection of a particular Zener diode.

The semiconductor switch 105 is transitioned to an OFF state (440). The semiconductor switch 105 is transitioned to the OFF state when V_{gs} is 0V or less. An input voltage is provided to the third terminal 105c. The input voltage is a voltage that is intended to transition the semiconductor switch 105 to the OFF state. In the example of FIG. 3, the input voltage is V_{OUT}, the amplified output of the amplifier 210. As discussed above, the voltage of V_{OUT} is within a range of voltages determined by the voltage at the high power supply terminal 216 and the low power supply terminal 218. For example, the Zener diode may have a reverse voltage of 5V. In this example, the voltage of the second terminal 105b is about 5V greater than the voltage of the low power supply terminal 218 of the amplifier 210. The lowest value of Vₒᵤₜ is determined by the voltage at the low power supply terminal 218, and, thus, the lowest value of Vₒᵤₜ is also about 5V lower than the voltage at the second terminal 105b. As such, V_{OUT}, which is provided to the third terminal 105c of the semiconductor switch, drives the voltage between the third terminal 105c and the second terminal 105b (V_{gs}) negative and the semiconductor switch 105 can be transitioned to the OFF state.

In this way, the charge store 350 may replace a second external floating power supply (separate from and in addition to the voltage source 240) that would otherwise be used to provide the lower rail of the amplifier 210, allowing the driving apparatus 320 to include only a single floating external voltage source (the voltage source 240). This configuration can result in the driving apparatus 320 being a simpler circuit that, as compared to a configuration that includes two floating external voltage sources, is less error prone, uses fewer components, and has a smaller footprint.

Additionally, the Zener diode 352 limits the amount of voltage that the charge store 350 provides, and can limit the voltage stored in the charge store to within 1% of a particular value. Thus, the driving apparatus 320 has provides the amplifier 210 with both a regulated positive rail or voltage supply (the voltage at the high power supply terminal 216, which is supplied by the voltage source 240) and a regulated negative rail or voltage supply (the voltage at the low power supply terminal 218, which is based on the charge stored in the capacitive element 357 of the charge store 350).

The resistive element 356, which is in parallel with the capacitive element 357, acts as a bleeder resistor and removes excess charge from the capacitive element 357. When the semiconductor switch 105 remains in the OFF state for a relatively long period of time, the charge that is stored in the capacitive element 357 is removed from the capacitive element 357 through the resistive element 356. This allows the capacitive element 357 and the charge store 350 to be reset to a known state when the system 300 is turned off.

Other features are within the scope of the claims. For example, the amplifier 210 may include additional terminals other than those shown in FIGS. 2 and 3. The output terminal 214 of the amplifier 210 may be connected to the third terminal 105c of the semiconductor switch 105 through a resistive element.

The electrical network 330 (FIG. 3) may include more than one diode. In some implementations, the electrical network 330 does not include the resistive element 336, and the cathode 334 of the diode 332 is connected directly to the first terminal 105a of the semiconductor switch 105.

The driving apparatus 220, 320 may be used without the amplifier 210. In these implementations, a voltage signal intended to transition the semiconductor switch 105 to the OFF state or to the ON state is provided directly to the third terminal 105c.

What is claimed is:

1. An apparatus comprising:
an electrical network configured for connection to a first terminal of a semiconductor switch;
a first voltage source connected to the electrical network;
a second voltage source configured for connection to a second terminal of the semiconductor switch and to the first voltage source, the second voltage source comprising a capacitive element configured to store electrical charge, the capacitive element receiving and storing electrical charge when the electrical network and the semiconductor switch conduct current, and the second voltage source providing a voltage based on the capacitive element, the voltage provided by the second voltage source bringing the second terminal of the semiconductor switch to a voltage that is greater than the lowest voltage that a third terminal of the semiconductor switch receives.

2. The apparatus of claim 1, wherein
the semiconductor switch does not conduct current when the voltage of the third terminal of the semiconductor switch relative to the second terminal of the semiconductor switch is less than an OFF voltage, and
the voltage provided by the second voltage source brings the second terminal of the semiconductor switch to a voltage that is greater than the lowest voltage that the third terminal of the semiconductor switch receives by an amount that is at least equal to the OFF voltage.

3. The apparatus of claim 2, wherein the OFF voltage of the semiconductor switch is less than zero.

4. The apparatus of claim 1, further comprising a voltage regulator connected to the second voltage source.

5. The apparatus of claim 4, wherein the voltage regulator comprises a Zener diode, and the Zener diode is connected in parallel with the capacitive element of the second voltage source.

6. The apparatus of claim 5, wherein the capacitive element of the second voltage source comprises a single capacitor.

7. The apparatus of claim 1, wherein the electrical network comprises a diode.

8. The apparatus of claim 1, further comprising an amplifier, the amplifier comprising an input terminal, an output terminal, a high power supply terminal, and a low power supply terminal, and wherein:
the output terminal of the amplifier is connected to the third terminal of the semiconductor switch,
the high power supply terminal of the amplifier is connected to the first voltage source, and
the low power supply terminal of the amplifier is connected to the second voltage source.

9. The apparatus of claim 8, wherein the lowest voltage that the third terminal of the semiconductor switch receives is the voltage of the low power supply terminal of the amplifier.

10. The apparatus of claim 2, wherein the electrical network is configured to conduct current when the semiconductor switch conducts current from the first terminal of the semiconductor switch to the second terminal of the semiconductor switch.

11. The apparatus of claim 8, further comprising the semiconductor switch.

12. The apparatus of claim 11, wherein the semiconductor switch comprises one of a silicon carbide (SiC) metal-oxide semiconductor field-effect (MOSFET) transistor and an insulated-gate bipolar transistor (IGBT).

13. The apparatus of claim 1, wherein the capacitive element of the second voltage source receives electrical charge from the first voltage source when the electrical network and the semiconductor switch conduct current.

14. A method of controlling a semiconductor switch, the method comprising:
connecting an electrical network to a first terminal of the semiconductor switch, the semiconductor switch comprising the first terminal, a second terminal, and a third terminal, the semiconductor switch conducting current from the first terminal to the second terminal in an ON state and not conducting current from the first terminal to the second terminal in an OFF state,
conducting current through the electrical network when current flows from the first terminal of the semiconductor switch to the second terminal of the semiconductor switch to charge a capacitive element, the capacitive element being connected to the second terminal of the semiconductor switch;
providing a voltage at the second terminal based on the charge in the capacitive element, the provided voltage bringing the second terminal of the semiconductor switch to a voltage that is greater than the lowest voltage that the third terminal of the semiconductor switch receives; and
applying an input voltage to the third terminal of the semiconductor switch, the input voltage bringing the voltage of the third terminal to a voltage that is less than the voltage at the second terminal of the semiconductor switch to transition the semiconductor switch to the OFF state.

15. The method of claim 14, wherein conducting current through the electrical network comprises conducting current through a forward biased diode and a resistive element, the resistive element limiting the amount of charge that flows to the capacitive element.

16. The method of claim 14, wherein:
conducting current through the electrical network when current flows from the first terminal of the semiconductor switch to the second terminal of the semiconductor switch to charge the capacitive element comprises charging the capacitive element to a voltage that is no greater than a reverse voltage of a Zener diode in parallel with the capacitive element, and
providing a voltage at the second terminal based on the charge in the capacitive element, the provided voltage bringing the second terminal of the semiconductor switch to a voltage that is greater than the lowest voltage that the third terminal of the semiconductor switch receives comprises providing a regulated voltage to the second terminal.

17. A negative charge pump apparatus for connection to a semiconductor switch, the negative charge pump apparatus comprising:
an electrical network comprising:
a diode, and
a resistive element in series with the diode; and
a voltage source configured for connection to the resistive element of the electrical network through the semiconductor switch, the voltage source comprising:
a capacitive element, and
a Zener diode in parallel with the capacitive element.

18. The negative charge pump apparatus of claim 17, wherein the capacitive element of the floating voltage source comprises a single capacitor.

19. The negative charge pump apparatus of claim 18, wherein the voltage source further comprises a second resistive element connected in parallel with the Zener diode and the capacitor.

20. The negative charge pump apparatus of claim 17, further comprising another voltage source, the other voltage source being connected between the electrical network and the voltage source.
